(19) United States
(12) Patent Application Publication
(10) Pub. No.: US 2025/0096142 A1
(43) Pub. Date: Mar. 20, 2025

(54) ELECTRO-OPTIC BRIDGE CHIPS FOR CHIP-TO-CHIP COMMUNICATION

(71) Applicant: GlobalFoundries U.S. Inc., Malta, NY (US)

(72) Inventor: Jae Kyu Cho, Niskayuna, NY (US)

(21) Appl. No.: 18/368,152

(22) Filed: Sep. 14, 2023

(51) Int. Cl. H01L 23/538; G02B 6/12; G02B 6/122; G02B 6/43; H01L 23/00; H01L 23/498; H01L 25/065

(52) U.S. Cl. CPC H01L 23/5381; G02B 6/12002; G02B 6/1228; G02B 6/43; H01L 23/49816; H01L 24/24; H01L 24/82; H01L 25/0655; H01L 2224/24155; H01L 2224/24227; H01L 2224/82101; H01L 2924/404

(57) ABSTRACT

Structures including an electro-optic bridge chip and methods of forming such structures. The structure comprises a photonics chip and an electro-optic bridge chip on a package substrate. The electro-optic bridge chip includes a waveguide core and an electrical trace line. A portion of the waveguide core is coupled to an optical coupler of the photonics chip.

### BACKGROUND

The present disclosure relates generally to semiconductor devices and integrated circuit fabrication and, more specifically, to structures including an electro-optic bridge chip and methods of forming such structures.

Photonics chips are used in many applications and systems including, but not limited to, data communication systems and data computation systems. A photonics chip includes a photonic integrated circuit comprised of photonic components, such as modulators, polarizers, and optical couplers, that are used to manipulate light received from a light source, such as an optical fiber or a laser.

Improved structures including an electro-optic bridge chip and methods of forming such structures are needed.

### SUMMARY

In an embodiment, a structure comprises a photonics chip and an electro-optic bridge chip on a package substrate. The electro-optic bridge chip includes a waveguide core and an electrical trace line. A portion of the waveguide core is coupled to an optical coupler of the photonics chip.

In an embodiment, a method comprises forming an electro-optic bridge chip including a waveguide core and an electrical trace line, attaching the electro-optic bridge chip to a package substrate, and attaching a photonics chip to the package substrate. A portion of the waveguide core is coupled to an optical coupler of the photonics chip.

### BRIEF DESCRIPTION OF THE DRAWINGS

The accompanying drawings, which are incorporated in and constitute a part of this specification, illustrate various embodiments of the invention and, together with a general description of the invention given above and the detailed description of the embodiments given below, serve to explain the embodiments of the invention. In the drawings, like reference numerals are used to indicate like features in the various views.

FIG. 1 is a cross-sectional view of a structure at an initial fabrication stage in accordance with embodiments of the invention.

FIG. 2 is a cross-sectional view of the structure at a fabrication stage subsequent to FIG. 1.

FIG. 3 is a cross-sectional view of the structure at a fabrication stage subsequent to FIG. 2.

FIG. 3A is an enlarged top view of a waveguide core associated with each dielectric layer in FIG. 3.

FIG. 4 is a cross-sectional view of the structure at a fabrication stage subsequent to FIG. 3.

FIG. 5 is a cross-sectional view of the structure at a fabrication stage subsequent to FIG. 4.

FIG. 6 is a cross-sectional view of the structure at a fabrication stage subsequent to FIG. 5.

FIG. 6A is a bottom view of the optical couplers of the photonic chips in FIG. 6.

FIG. 7 is a top view of a structure in accordance with alternative embodiments of the invention.

### DETAILED DESCRIPTION

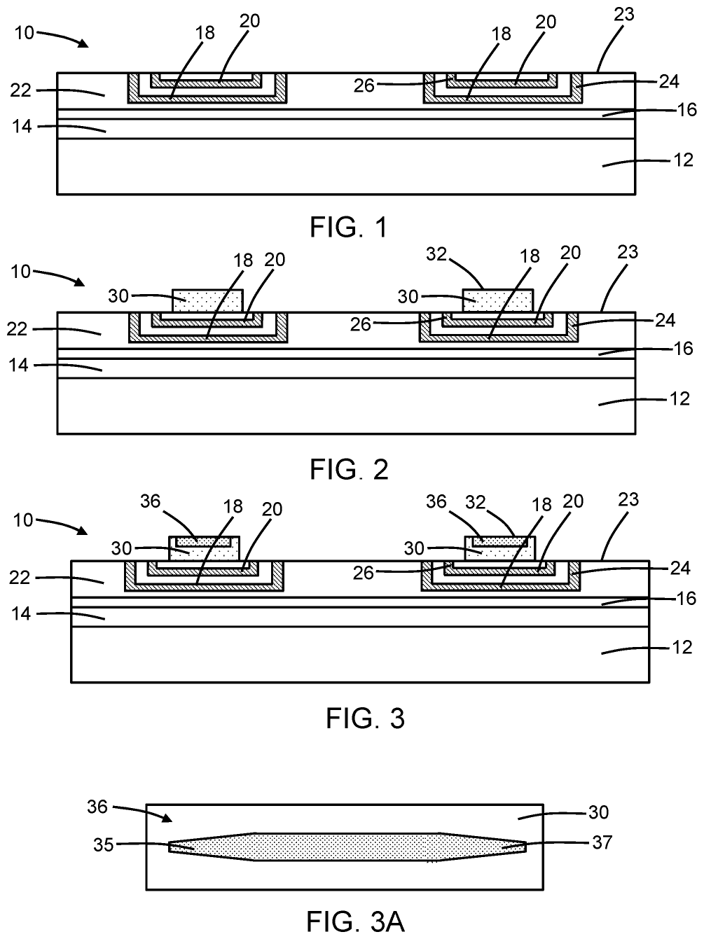

With reference to FIG. 1 and in accordance with embodiments of the invention, a structure 10 includes a carrier substrate 12, a release layer 14 coating a front surface of the carrier substrate 12, and a support substrate 16 that is releasably attached to the front surface of the carrier substrate 12 by the release layer 14. The carrier substrate 12 may be a glass support panel or a wafer, and the release layer 14 may provide a temporary bond between the carrier substrate 12 and the support substrate 16. For example, the release layer 14 may be configured to convert light to heat under laser irradiation in order to release the support substrate 16 from the carrier substrate 12. In an embodiment, the support substrate 16 may be comprised of silicon. In an embodiment, the support substrate 16 may be a thinned silicon wafer.

Multiple instances of electrical trace lines 18, 20 may be formed in a set of dielectric layers 22 disposed on the support substrate 16. The dielectric layers 22 may be comprised of a dielectric material, such as silicon dioxide, and the dielectric layers 22 may have a top surface 23. The electrical trace lines 18, 20 may be formed in the dielectric layers 22 by patterning trenches and filling the trenches with a conductor, such as copper. Vias 24 may be formed in the dielectric layers 22 that are coupled to the opposite ends of the electrical trace line 18. Vias 26 may be formed in the dielectric layers 22 that are coupled to the opposite ends of the electrical trace line 18. The vias 24, 26 may be formed by patterning via openings in the dielectric layers 22 and filling the via openings with a conductor, such as copper. The electrical trace line 18 and vias 24 define an electrical interconnect, and electrical trace line 20 and vias 26 define another electrical interconnect. In alternative embodiments, additional electrical interconnects including dielectric layers and electrical trace lines may be added to the structure 10. The support substrate 16 provides mechanical support for the dielectric layers 22.

With reference to FIG. 2 in which like reference numerals refer to like features in FIG. 1 and at a subsequent fabrication stage, a dielectric layer 30 may be disposed on the top surface 23 of the dielectric layers 22 and over each set of the electrical trace lines 18, 20. The dielectric layer 30 is dimensioned such that the vias 24, 26 are not covered and are instead exposed. In an embodiment, the dielectric layer 30 may be centered over the electrical trace lines 18, 20. In an embodiment, the dielectric layer 30 may be comprised of a polymer, such as polyimide, that is formed on the top surface 23 as a coating and patterned by lithography and etching processes. In an embodiment, the dielectric layer 30 may be comprised of glass block that may be positioned by a pick-and-place operation on the top surface 23. The dielectric layer 30 has a bottom surface that adjoins the topmost of the dielectric layers 22 and a top surface 32 that is opposite from the bottom surface. The top surface 32 of the dielectric layer 30 is elevated above the top surface 23 of the dielectric layers 22, and the dielectric layer 30 may be disposed fully above the top surface 23 of the dielectric layers 22.

With reference to FIGS. 3, 3A in which like reference numerals refer to like features in FIG. 2 and at a subsequent fabrication stage, a waveguide core 36 may be formed in or on the top surface 32 of each of the dielectric layers 30. In an embodiment and as best shown in FIG. 3A, a tapered section 35 and a tapered section 37 may define optical couplers that are disposed at opposite ends of each waveguide core 36. In an embodiment, the waveguide cores 36 may be inscribed by laser writing to locally increase the refractive index of a portion of the material of the dielectric layer 30. In an embodiment, the waveguide cores 36 may be formed from a layer that is deposited and patterned by lithography and etching processes. Each waveguide core 36 defines an optical interconnect. In an alternative embodiment, multiple parallel waveguide cores 36 may be formed in each of the dielectric layers 30 to provide multiple optical interconnects.

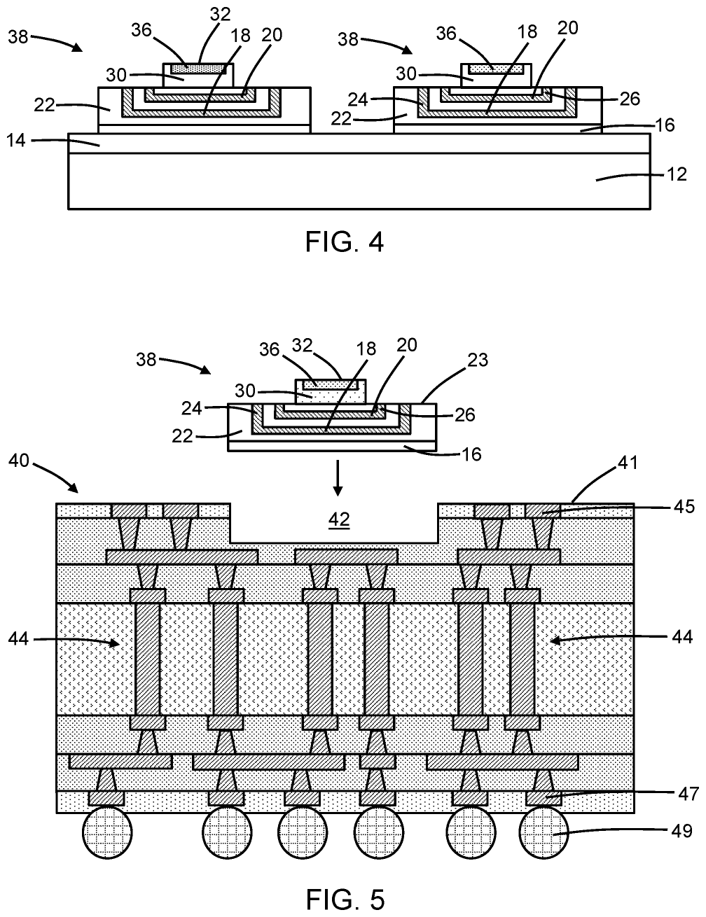

With reference to FIG. 4 in which like reference numerals refer to like features in FIGS. 3, 3A and at a subsequent fabrication stage, electro-optic bridge chips 38 may be formed by singulation of the structure 10 using a mechanical saw, a laser cutter, or a combination of these or other singulating techniques. Following singulation, the release layer 14 may be processed to debond the singulated electro-optic bridge chips 38 from the carrier substrate 12. For example, the release layer 14 may be subjected to laser irradiation that is converted by the release layer 14 to heat, which elevates the temperature of the release layer 14 and reduces the adhesion such that the electro-optic bridge chips 38 can be removed. The section of the support substrate 16 includes in each singulated electro-optic bridge chip 38 provides mechanical support after removal from the carrier substrate 12. Each of the electro-optic bridge chips 38 is a hybrid construct that includes one of the dielectric layers 30, an optical interconnect provided by one of the waveguide cores 36, and electrical interconnects provided by a set of the electrical trace lines 18, 20 and vias 24, 26.

With reference to FIG. 5 in which like reference numerals refer to like features in FIG. 4 and at a subsequent fabrication stage, each electro-optic bridge chip 38 may be assembled with a package substrate 40. In that regard, a recess 42 may be formed as a cavity in a top surface 41 of the package substrate 40. In an embodiment, the recess 42 may be formed by a milling operation, such as by laser milling or machine milling. The recess 42 has dimensions and a shape that is correlated to the dimensions and shape of the electro-optic bridge chip 38. In an embodiment, the electro-optic bridge chip 38 may be adhesively bonded to one or more of the surfaces of the package substrate 40 surrounding the recess 42. Due to the placement inside of the recess 42, the electro-optic bridge chip 38 may be surrounded by, or embedded in, the package substrate 40.

The top surface 32 of the dielectric layer 30 and the top surface 23 of the dielectric layers 22, except an area covered by the dielectric layer 30, are exposed after the electro-optic bridge chip 38 is attached to the package substrate 40. In an embodiment, the top surface 23 may be coplanar with the top surface 41 of the package substrate 40, which may be achieved through selection of the thickness of the electro-optic bridge chip 38 and selection of the depth of the recess 42. The vias 24, 26 are accessible at the top surface 23 of the dielectric layers 22 for establishing electric connections with the electrical trace lines 18, 20, which define electrical pathways of the electrical interconnects that extend laterally in the electro-optic bridge chip 38. In an embodiment, the electrical interconnects incorporated into the electro-optic bridge chip 38 may be used for power and ground. The top surface 32 of the dielectric layer 30 is disposed above the top surface 41 of the package substrate 40 such that the waveguide core 36 is also disposed above the top surface 41 and accessible for establishing an optical pathway in the electro-optic bridge chip 38. In an embodiment, the optical interconnect incorporated into the electro-optic bridge chip 38 may be used for signal processing.

The package substrate 40 includes package interconnects 44 for establishing electrical communication with one or more chips that are subsequently attached to the package substrate 40. The package substrate 40 may include bond pads 45 that are located at the top surface 41 and bond pads 47 that are located at a bottom surface. The bond pads 47 may be populated by solder balls 49. Each package interconnect 44 may be terminated at opposite ends by the bond pads 45, 47 to establish electrical pathways extending through the thickness of the package substrate 40. In an embodiment, the package substrate 40 may be a printed circuit board laminate that comprises an organic matrix in which the package interconnects 44 are embedded. In an embodiment, the top surface 23 of the dielectric layers 22 may be coplanar with the top surface 41.

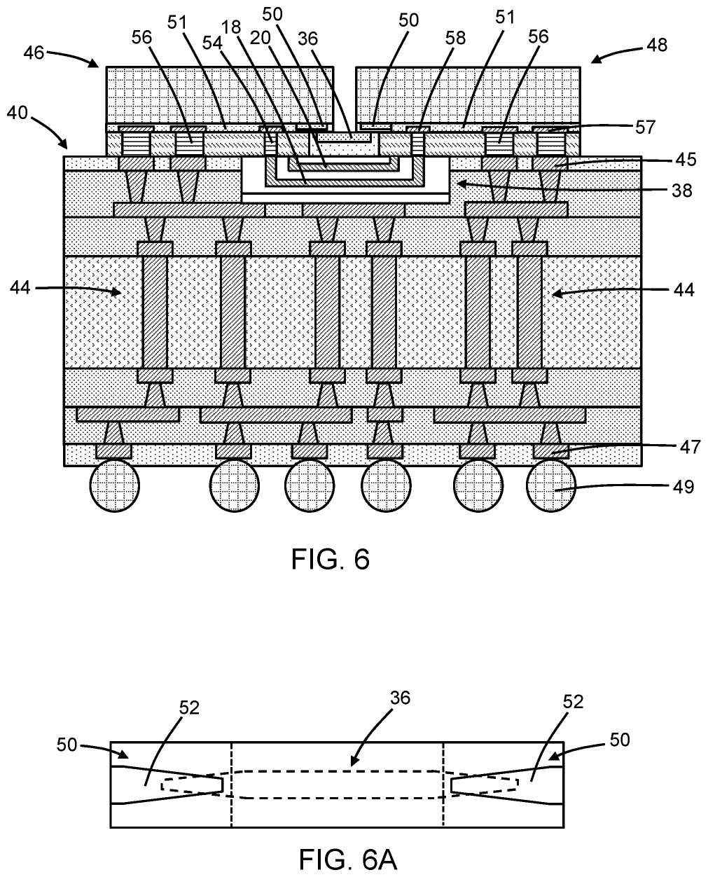

With reference to FIGS. 6, 6A in which like reference numerals refer to like features in FIG. 5 and at a subsequent fabrication stage, a photonics chip 46 and a photonics chip 48 may be disposed on the package substrate 40. The photonics chip 46 is positioned on the package substrate 40 with a back-end-of-line stack 51 adjacent to a portion of the electro-optic bridge chip 38, and the photonics chip 48 is positioned on the package substrate 40 with a back-end-of-line stack 51 adjacent to a different portion the electro-optic bridge chip 38. Each of the photonics chips 46, 48 includes photonic components, such as modulators, polarizers, and optical couplers, arranged in a photonic integrated circuit that is configured to manipulate light received from a light source, such as an optical fiber or a laser.

Each of the photonics chips 46, 48 also includes an optical coupler 50 that provides an interface for light transfer to and from the respective photonic integrated circuit. In an embodiment, each optical coupler 50 may be a tapered section 52 (FIG. 6A) that is comprised of patterned silicon or silicon nitride. A portion of the optical coupler 50 of the photonics chip 46 overlaps with a portion of the waveguide core 36. In an embodiment, the tapered section 52 of the optical coupler 50 of the photonics chip 46 may overlap with the tapered section 35 of the waveguide core 36. A portion of the optical coupler 50 of the photonics chip 48 overlaps with a portion of the waveguide core 36. In an embodiment, the tapered section 52 of the optical coupler 50 of the photonics chip 48 may overlap with the tapered section 37 of the waveguide core 36.

The back-end-of-line stacks 51 have dielectric layers and interconnects in the dielectric layers that may be coupled with the photonic components, such as photodetectors and modulators, of the photonic integrated circuit are electrically active. Each of the back-end-of-line stacks 51 may include bond pads 58 that are physically and electrically coupled by electrical connections 54, such as solder bumps or pillars capped by a solder layer, to the electrical trace lines 18, 20 in order to establish electrical communication between the different photonics chips 46, 48. Each of the back-end-of-line stacks 51 may include bond pads 57 that are physically and electrically coupled by electrical connections 56, such as solder bumps or pillars capped by a solder layer, to the package interconnects 44 in order to establish external electrical connections to each of the photonics chips 46, 48. The electrical connections 54, 56 may be established by a solder reflow process.

In an embodiment, each back-end-of-line stack 51 may include an opening in which the optical coupler 50 is positioned. The opening in each back-end-of-line stack 51 may be filled by a homogeneous dielectric material, such as silicon dioxide, that replaces a removed portion of the back-end-of-line stack 51.

In use, optical signals may be transferred from the photonics chip 46 to the photonics chip 48 by coupling light from the optical coupler 50 of the photonics chip 46 to the waveguide core 36 and then, after the light propagates along the length of the waveguide core 36, coupling the light from the waveguide core 36 to the optical coupler 50 of the photonics chip 48. Conversely, optical signals may be transferred from the photonics chip 48 to the photonics chip 46 by coupling light from the optical coupler 50 of the photonics chip 48 to the waveguide core 36 and then, after the light propagates along the length of the waveguide core 36, coupling the light from the waveguide core 36 to the optical coupler 50 of the photonics chip 46. Electrical signals are communicated between the photonics chips 46, 48 through the electrical trace lines 18, 20 and vias 24, 26.

Multiple photonics chips 46, 48 are directly routed through the electro-optic bridge chip 38. The electro-optic bridge chip 38 establishes an interface for optical communication and an interface for electrical communication between the photonics chips 46, 48. The electro-optic bridge chip 38 includes the electrical trace lines 18, 20 and vias 24, 26 providing the chip-to-chip electrical interconnects enabling electrical communication. The photonics chips 46, 48 may be electrically coupled to each other by the chip-to-chip electrical interconnects. The electro-optic bridge chip 38 includes the chip-to-chip optical interconnect provided by the waveguide core 36 enabling optical communication. The photonics chips 46, 48 are optically coupled to each other by the chip-to-chip optical interconnect. The hybrid combination of chip-to-chip electrical and optical interconnects may enable a high bandwidth data rate that is unachievable with metal-based interconnects alone. The electro-optic bridge chip 38 may eliminate the need for costly interposers and through-silicon vias.

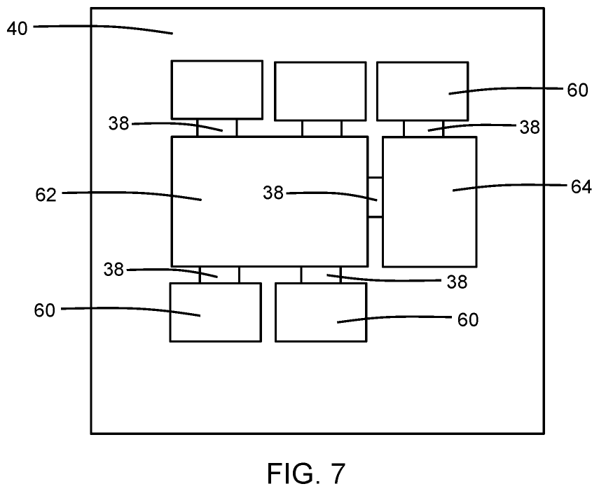

With reference to FIG. 7 and in accordance with alternative embodiments, electro-optic bridge chips 38 may be deployed to couple multiple chips of different types for optical and electrical communication. In an embodiment, multiple photonics chips 60, an electronic chip 62, and a memory chip 64 may be assembled on the package substrate 40. The photonics chips 60 may be similar or identical to the photonics chips 46, 48. The electronic chip 62 may be a non-photonics chip that includes electronic components, such as transistors, that form a functional electronic integrated circuit, such as an application-specific integrated circuit. In an embodiment, the memory chip 64 may be a non-photonics chip in the form of a High Bandwidth Memory (HBM) stack. Each of the chips 60, 62, 64 may include an optical coupler, which may be similar to the optical coupler 50, that is coupled to the waveguide core 36 in order to enable optical communication. In alternative embodiments, other arrangements of photonics chips, electronic chips, and/or memory chips may be assembled on the package substrate 40 and coupled for electrical and optical communication by instances of the electro-optic bridge chip 38.

The methods as described above are used in the fabrication of integrated circuit chips. The resulting integrated circuit chips can be distributed by the fabricator in raw wafer form (e.g., as a single wafer that has multiple unpackaged chips), as a bare die, or in a packaged form. The chip may be integrated with other chips, discrete circuit elements, and/or other signal processing devices as part of either an intermediate product or an end product. The end product can be any product that includes integrated circuit chips, such as computer products having a central processor or smartphones.

References herein to terms modified by language of approximation, such as “about”, “approximately”, and “substantially”, are not to be limited to the precise value specified. The language of approximation may correspond to the precision of an instrument used to measure the value and, unless otherwise dependent on the precision of the instrument, may indicate +/−10% of the stated value(s).

References herein to terms such as “vertical”, “horizontal”, etc. are made by way of example, and not by way of limitation, to establish a frame of reference. The term “horizontal” as used herein is defined as a plane parallel to a conventional plane of a semiconductor substrate, regardless of its actual three-dimensional spatial orientation. The terms “vertical” and “normal” refer to a direction in the frame of reference perpendicular to the horizontal, as just defined. The term “lateral” refers to a direction in the frame of reference within the horizontal plane.

A feature “connected” or “coupled” to or with another feature may be directly connected or coupled to or with the other feature or, instead, one or more intervening features may be present. A feature may be “directly connected” or “directly coupled” to or with another feature if intervening features are absent. A feature may be “indirectly connected” or “indirectly coupled” to or with another feature if at least one intervening feature is present. A feature “on” or “contacting” another feature may be directly on or in direct contact with the other feature or, instead, one or more intervening features may be present. A feature may be “directly on” or in “direct contact” with another feature if intervening features are absent. A feature may be “indirectly on” or in “indirect contact” with another feature if at least one intervening feature is present. Different features “overlap” if a feature extends over, and covers a part of, another feature.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A structure comprising:
a package substrate;
a first photonics chip on the package substrate, the first photonics chip including an optical coupler and a bond pad; and
an electro-optic bridge chip on the package substrate, the electro-optic bridge chip including a waveguide core and an electrical trace line, the electrical trace line coupled to the bond pad of the first photonics chip, and the waveguide core including a first portion that is coupled to the optical coupler of the first photonics chip.

2. The structure of claim 1 wherein the package substrate includes a recess, and the electro-optic bridge chip is disposed inside the recess.

3. The structure of claim 2 wherein the package substrate includes a plurality of electrical interconnects that are coupled to the first photonics chip.

4. The structure of claim 1 wherein the electro-optic bridge chip includes a dielectric layer, and the waveguide core is disposed in the dielectric layer.

5. The structure of claim 4 wherein the package substrate has a top surface, and the waveguide core is disposed in the dielectric layer above the top surface of the package substrate.

6. The structure of claim 4 wherein the package substrate has a top surface, and the dielectric layer has a top surface that is disposed above the top surface of the package substrate.

7. The structure of claim 4 wherein the package substrate has a top surface, and the dielectric layer is disposed on the top surface of the package substrate.

8. The structure of claim 4 wherein the dielectric layer has a top surface, and the waveguide core is disposed adjacent to the top surface of the dielectric layer.

9. The structure of claim 1 wherein the package substrate has a top surface, the electro-optic bridge chip includes one or more dielectric layers, the electrical trace line is disposed in the one or more dielectric layers, and the waveguide core is disposed over the electrical trace line.

10. The structure of claim 9 wherein the electro-optic bridge chip includes a support substrate, and the one or more dielectric layers are disposed on the support substrate.

11. The structure of claim 9 wherein the one or more dielectric layers have a top surface that is coplanar with the top surface of the package substrate.

12. The structure of claim 1 wherein the waveguide core is centered over the electrical trace line.

13. The structure of claim 1 wherein the first portion of the waveguide core is a tapered section, the optical coupler includes a tapered section, and the tapered section of the waveguide core overlaps with the tapered section of the optical coupler.

14. The structure of claim 1 further comprising:
a second photonics chip on the package substrate, the second photonics chip including an optical coupler,
wherein the waveguide core of the electro-optic bridge chip includes a second portion that is coupled to the optical coupler of the second photonics chip.

15. The structure of claim 14 wherein the first photonics chip includes a bond pad, the second photonics chip includes a bond pad, and the electrical trace line couples the bond pad of the first photonics chip to the bond pad of the second photonics chip.

16. The structure of claim 1 further comprising:
a non-photonics chip on the package substrate, the non-photonics chip including an optical coupler,
wherein the waveguide core of the electro-optic bridge chip includes a second portion that is coupled to the optical coupler of the non-photonics chip.

17. The structure of claim 16 wherein the non-photonics chip is an application-specific integrated circuit.

18. A method comprising:
forming an electro-optic bridge chip including a waveguide core and an electrical trace line;
attaching the electro-optic bridge chip to a package substrate; and
attaching a first photonics chip to the package substrate, wherein the first photonics chip includes an optical coupler, and the waveguide core includes a first portion that is coupled to the optical coupler of the first photonics chip.

19. The method of claim 18 further comprising:
attached a second photonics chip to the package substrate,
wherein the second photonics chip includes an optical coupler, and the waveguide core of the electro-optic bridge chip includes a second portion that is coupled to the optical coupler of the second photonics chip.

20. The method of claim 19 wherein the first photonics chip includes a bond pad, the second photonics chip includes a bond pad, and the electrical trace line couples the bond pad of the first photonics chip to the bond pad of the second photonics chip.
